(19) United States
(12) Patent Application Publication
(10) Pub. No.: US 2025/0324529 A1
(43) Pub. Date: Oct. 16, 2025

(54) ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/045,550

(22) Filed: Feb. 5, 2025

(30) Foreign Application Priority Data
Feb. 14, 2024 (JP) 2024-020364

(51) Int. Cl. H05K 7/02; H05K 7/06; H05K 7/20

(52) U.S. Cl. CPC H05K 7/023; H05K 7/06; H05K 7/20436; H05K 7/20509

(57) ABSTRACT

Provided is an electronic module where a distance between heat radiation surfaces disposed on both surfaces of the electronic module and external connection terminal can be properly controlled. An electronic module includes: a first board; a first electronic element disposed on the first board; a second board; a second electronic element disposed on the second board; external connection terminals, and an internal connection terminal made to pass through the external connection terminals, the external connection terminals being fixed to the internal connection terminal at a predetermined position between the first board and the second board, wherein the internal connection terminal is disposed between the first board and the second board or the second electronic element, or, between the first electronic element and the second board or the second electronic element.

### CROSS REFERENCE TO RELATED APPLICATIONS

The present application is based on, and claims priority from JP Application Serial Number 2024-020364, filed on Feb. 14, 2024, the disclosure of which is hereby incorporated by reference herein in its entirety.

### TECHNICAL FIELD

The present invention relates to an electronic module.

### BACKGROUND ART

Conventionally, there has been known an electronic module where a heat radiation surface is disposed on both surfaces of the electronic module, and heat is radiated from both surfaces of the electronic module. Patent document 1 describes an electronic module (semiconductor device 900) that includes an electronic element (semiconductor element) 910, a pair of boards 920, 930 that are disposed so as to sandwich the electronic element 910 therebetween: and a conductive spacer 940 that is interposed between the board 930 and the electronic element 910 (see FIG. 7). The board 920, 930 includes an insulation board 921, 931, a surface metal body 922, 932 that is connected to the corresponding electrodes, and a heat radiation member (back surface metal body) 923, 933. Heat generated from the electronic element 910 is radiated from both surfaces of the electronic module 900 through the conductive spacer 940, the surface metal bodies 922, 932 and the heat radiation members 923, 933.

### CITATION LIST

### Patent Document

[Patent document 1] JP-A-2022-181822

In a case of an electronic module where the electronic module 900 treats a high voltage, to secure an insulation distance between the heat radiation members 923, 933 disposed on both surfaces of the electronic module 900 and external connection terminals (power source terminal, output terminal) 941, 942, it is desirable to arrange the external connection terminals 941, 942 at an intermediate position in a thickness direction between the heat radiation members 923, 933 disposed on both surfaces.

In a case where the external connection terminals 941, 942 are arranged at the intermediate position in the thickness direction between the heat radiation members 923, 933 disposed on both surfaces of the electronic module 900, as a method of electrically connecting the external connection terminals 941, 942 with wirings not illustrated in the drawing that are formed on the electronic element 910 and the boards 920, 930, a method of bending the external connection terminal 941 in the direction that the board 930 is disposed, and the external connection terminal 941 is connected to a wiring formed on the board 930 as illustrated in FIG. 7, a method of securing an insulation distance between the external connection terminals 941, 942 and heat radiation surfaces by increasing a thickness of the board 920 or the like can be named.

However, in the method where the external connection terminal 941 is bent, a control of a distance between the external connection terminal 941 and the board 930 is not easy and hence, there is a case where an insulation distance between the external connection terminal 941 and the wiring disposed on the board 930 cannot be secured. Further, there also exists a drawback that the external connection terminal 941 is brought into another electronic element that is disposed on the board 930 at a portion where the external connection terminal 941 is bent. On the other hand, in the method where a thickness of the board 920 is increased, although it is possible to secure an insulation distance between the heat radiation member 923 and the external connection terminal 942, there exists a drawback that it is difficult to secure an insulation distance between a wiring not illustrated in the drawing and the external connection terminal 941.

### SUMMARY OF INVENTION

### Technical Problem

The present invention has been made in view of the above-mentioned drawbacks, and it is an object of the present invention to provide an electronic module that has a heat radiation surface on both surfaces thereof, and arranges an external connection terminal between a first board and a second board, wherein a distance between the heat radiation surfaces disposed on both surfaces of the electronic module and the external connection terminal can be properly controlled.

### Solution to Problem

An electronic module according to the present invention includes: a first board; a first electronic element disposed on the first board; a second board; a second electronic element disposed on the second board; an external connection terminal, and an internal connection terminal made to pass through the external connection terminal, the external connection terminal being fixed to the internal connection terminal at a predetermined position between the first board and the second board, wherein the internal connection terminal is disposed between the first board and the second board or the second electronic element, or, between the first electronic element and the second board or the second electronic element.

### Advantageous Effect of the Invention

The electronic module according to the present e invention includes the first board, the second board, the external connection terminal, and the internal connection terminal that is made to pass through the external connection terminal. The internal connection terminal is made to pass through the external connection terminal, and fixes the external connection terminal at a predetermined position between the first board and the second board. In the electronic module according to the present invention, a distance between the first board and the second board is restricted by a length of the internal connection terminal. Accordingly, by controlling a length of the internal connection terminal, it is possible to control the distance between the first board and the second board properly without bending the external connection terminal or without using a thick board. Further, the external connection terminal is fixed at the predetermined position between the first board and the second board by the internal connection terminal and hence, the distance between the first board and the external connection terminal and the distance between the second board and the external connection terminal can be also properly controlled. According to the present invention, it is possible to provide the electronic module where a heat radiation surface is formed on both surfaces of the electronic module, and the external connection terminal is disposed between the first board and the second board, wherein the distance between the heat radiation surfaces disposed on both surfaces of the electronic module and the external connection terminal can be properly controlled.

### BRIEF DESCRIPTION OF DRAWINGS

FIG. 1 is a perspective view of an electronic module 1 according to an embodiment. In FIG. 1, an illustration of a mold resin 40 that constitutes one of constitutional elements of the electronic module 1 is omitted.

FIG. 2 is an external appearance view of the electronic module 1 according to the embodiment.

FIG. 3 is a side view illustrating the internal structure of the electronic module 1 according to the embodiment. In FIG. 3, the illustration of the mold resin 40 and an internal connection terminal 36a that constitute the constitutional elements of the electronic module 1 are omitted.

FIG. 4A and FIG. 4B are plan views illustrating the internal structure of the electronic module 1 according to the embodiment. FIG. 4A and FIG. 4B are plan views of the internal structure of the electronic module 1. In FIG. 4A, the illustration of a second board 20, a second electronic element 23 and the mold resin 40 that constitute constitutional elements of the electronic module 1 is omitted. In FIG. 4B, in addition to the constitutional elements whose illustration is omitted in FIG. 4A, the illustration of the portions of internal connection terminal 36c, 36d and external connection terminals 34a, 34b is omitted.

FIG. 5A and FIG. 5B are bottom views illustrating the internal structure of the electronic module 1 according to the embodiment. FIG. 5A and FIG. 5B are bottom views of the internal structure of the electronic module 1. In FIG. 5A, among constitutional elements of the electronic module 1, the illustration of the first board 10, the first electronic element 13 and the mold resin 40 is omitted. In FIG. 5B, in addition to the constitutional elements whose illustration is omitted in FIG. 5A, the illustration of portions of the internal connection terminals 36b, 36d and portions of the external connection terminals 34a, 34b is also omitted.

FIG. 6 is a left side view illustrating creepage distances L3, L4 of the electronic module 1 according to the embodiment.

FIG. 7 is a view illustrating an electronic module 900 according to the prior art.

### DESCRIPTION OF EMBODIMENTS

Hereinafter, an electronic module 1 according to the embodiment is described based on an embodiment illustrated in the drawings. It is not always the case that all various constitutional elements and all combinations of these constitutional elements described in the embodiment are indispensable as the solution to problems according to the present invention.

### Embodiment

### 1. Electronic Module

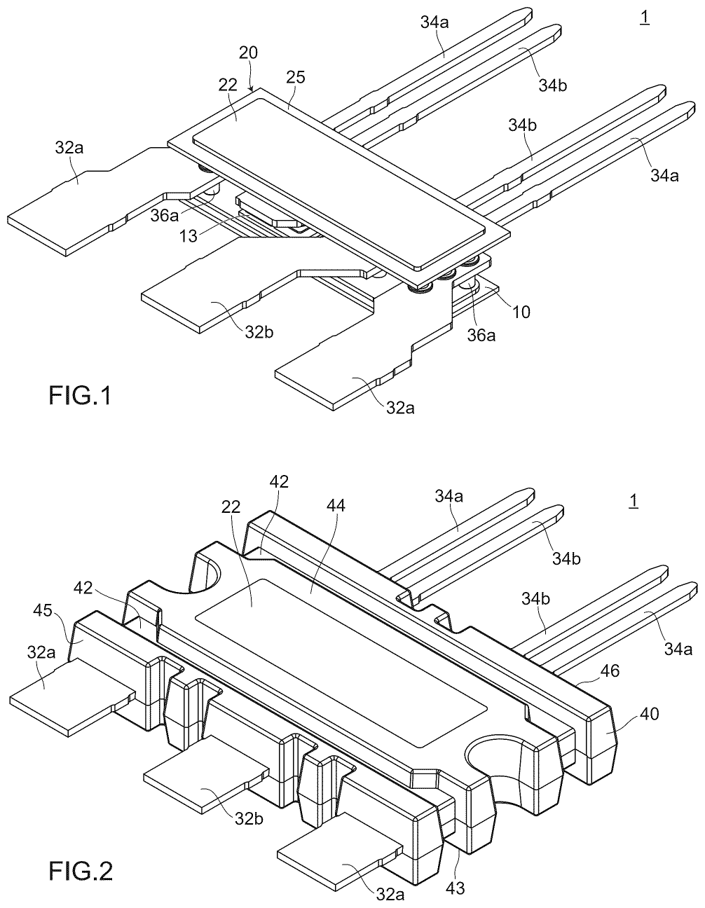

As illustrated in FIG. 1 to FIG. 5A and FIG. 5B, an electronic module 1 according to the embodiment includes a first board 10, a first heat radiation member 12, a first electronic element 13, a second board 20, a second heat radiation member 22, a second electronic element 23, external connection terminals 32a, 32b, external connection terminals 34a, 34b and internal connection terminals 36a, 36b, 36c, 36d. The electronic module 1 may include other constitutional elements besides the above-mentioned constitutional elements. Hereinafter, the respective constitutional elements are described.

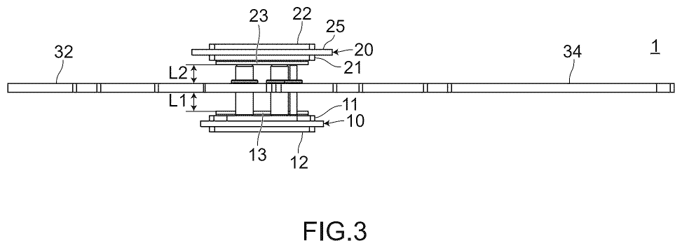

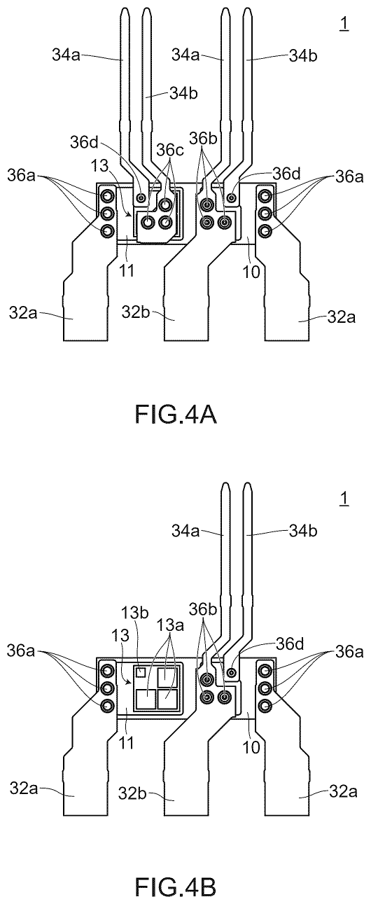

The first board 10 is a board where a first heat radiation member 12 that functions as a heat radiation surface is disposed on one surface of the board, and a first electronic element 13 is disposed on the other surface of the board (see FIG. 3, FIG. 4A and FIG. 4B). As the first board 10A, a ceramic board can be used. Preferably, a board having the structure where a copper plate is disposed on both surfaces of the ceramic plate (for example, a DCB board) can be used. In a case where the DCB board is used as the first board 10, the copper plate disposed on one surface can be used as the first heat radiation member 12. The first heat radiation member 12 is exposed to the outside of a mold resin 40. The first board 10 includes the wiring 11 (see FIG. 3, FIG. 4A and FIG. 4B), and is electrically connected to an electrode (not illustrated in the drawing) that is disposed on a surface of the first electronic element 13 that opposedly faces the first board 10.

In this specification, “electrically connected” includes not only a case where electricity supply portions of the constitutional elements are directly brought into contact with each other but also a case where such electricity supply portions are brought into contact with each other via an additional conductive constitutional element (for example, solder or a spacer).

The first electronic element 13 is an electronic element disposed on the first board 10. The first electronic element 13 is disposed on a surface of the first board 10 that opposedly faces the second board 20, and is sealed by the mold resin 40. The first electronic element 13 includes an electrode not illustrated in the drawing that is disposed on a surface that opposedly faces the first board 10, and electrodes 13a, 13b disposed on a surface that opposedly faces the second board 20. The electrode disposed on the surface that opposedly faces the first board 10 is electrically connected to the wiring 11 mounted on the first board 10. The electrodes 13a, 13b are electrically connected with internal connection terminals 36c, 36d. As the first electronic element 13, for example, a vertical type MOSFET can be named.

The second board 20 is a board disposed on a side where the first electronic element 13 of the first board 10 is disposed in a state where the second board 20 is spaced apart from the first board 10 and the first electronic element 13. With respect to the second board 20, “in a state where the second board 20 is spaced apart from the first board 10 and the first electronic element 13” means a state where the second board 20 is directly brought into contact with neither the first board 10 nor the first electronic element 13.

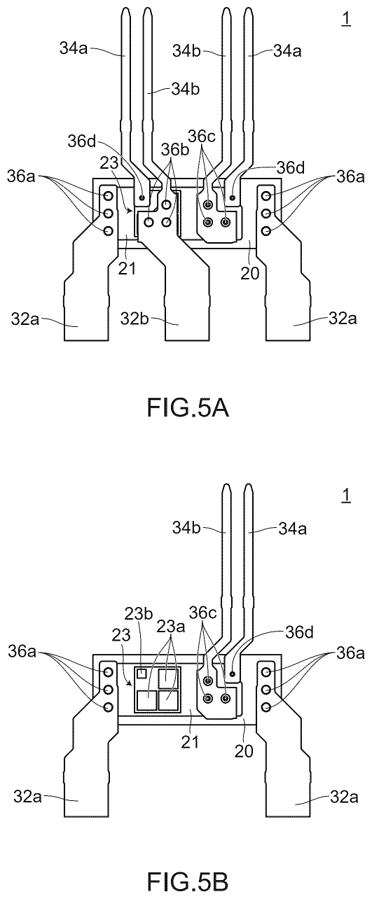

The second board 20 is a board where a second heat radiation member 22 that functions as a heat radiation surface is disposed on one surface of the board, and the second electronic element 23 is disposed on the other surface of the board. As the second board 20, a ceramic board can be used. Preferably, a board having the structure where a copper plate is disposed on both surfaces of the ceramic plate (a for example, DCB board) can be used. In a case where a DCB board is used as the second board 20, the copper plate disposed on one surface can be used as the second heat radiation member 22. The second heat radiation member 22 is exposed to the outside of the mold resin 40 (see FIG. 2). The second board 20 includes the wiring 21 (see FIG. 3, FIG. 5A and FIG. 5B), and is electrically connected to an electrode (not illustrated in the drawing) that is disposed on a surface of the second electronic element 23 that opposedly faces the second board 20.

The second electronic element 23 is an electronic element disposed on the second board 20. The second electronic element 23 is disposed on a surface of the second board 20 that opposedly faces the first board 10, and is sealed by the mold resin 40. The second electronic element 23 includes an electrode (not illustrated in the drawing) that is disposed on a surface that opposedly faces the second board 20, and electrodes 23a, 23b disposed on a surface that opposedly faces the first board 10. The electrode disposed on the surface that opposedly faces the second board 20 is electrically connected to the wiring 21 mounted on the second board 20. The electrodes 23a, 23b are electrically connected to the internal connection terminals 36b, 36d. As the second electronic element 23, for example, a vertical type MOSFET can be named.

There is a case where the internal connection terminals 36a, 36b, 36c, 36d (hereinafter “the internal connection terminals 36a, 36b, 36c, 36d” being collectively referred to as “internal connection terminals 36”) are connection terminals having a columnar shape that are disposed between the first board 10 and the second board 20 or the second electronic element 23, or are disposed between the first electronic element 13 and the second board 20 or the second electronic element 23.

The internal connection terminals 36 are made to pass through holes formed in the external connection terminals 32a, 32b and/or the external connection terminals 34a, 34b, and the external connection terminals 32a, 32b and/or the external connection terminals 34a, 34b are fixed to a predetermined position between the first board 10 and the second board 20.

To be more specific, one end of the internal connection terminal 36 is disposed on the first board 10 or on the first electronic element 13 disposed on the first board 10 via a bonding material (for example, solder). The other end of the internal connection terminal 36 is disposed on the second board 20 or the second electronic element 23 disposed on the second board 20 via a bonding material (for example, solder).

In such a configuration, as the internal connection terminal 36, the internal connection terminal 36 has a proper length corresponding to a place where the internal connection terminal 36 is disposed.

To be more specific, in a case where the internal connection terminal 36 is disposed between the first electronic element 13 and the second board 20, compared to a case where the internal connection terminal is disposed in a place where the first electronic element 13 is not disposed, the internal connection terminal 36 having a length shorter by an amount of thickness of the first electronic element 13 is used.

Further, in a case where the internal connection terminal 36 is disposed between the first board 10 and the second electronic element 23, the internal connection terminal 36 having a length shorter by an amount of thickness of the second electronic element 23 is used compared to a case where the internal connection terminal 36 is disposed in a place where the second electron element 23 is not disposed.

Further, in a case where the internal connection terminal 36 is disposed between the first electronic element 13 and the second electronic element 23, compared to a case where the internal connection terminal 36 is disposed in a place where neither the first electronic element 13 nor the second electronic element 23 is disposed, the internal connection terminal 36 having a length shorter by an amount of thickness of the first electronic element 13 or the second electronic element 23 is used.

In the electronic module 1 exemplified as the embodiment, the internal connection terminal 36a is disposed between a region where the first electronic element 13 of the first board 10 is not disposed and the region where the second electronic element 23 of the second board 20 is not disposed. On the other hand, the internal connection terminals 36c, 36d are disposed between the first electronic element 13 and the second board 20 (see FIG. 4A and FIG. 4B), and the internal connection terminals 36b, 36d are disposed between the first board 10 and the second electronic element 23. The internal connection terminals 36b, 36c, 36d are formed shorter than the internal connection terminal 36a by an amount of thickness of the first electronic element 13 or the second electronic element 23.

By using the internal connection terminal 36 having a proper length corresponding to the place where the internal connection terminal 36 is used, it is possible to properly control a distance between the first board 10 and the second board 20, or, it is possible to maintain the first board 10 and the second board 20 parallel to each other.

The internal connection terminals 36 are members that control the distance between the first board 10 and the second board 20 and, at the same time, are used for electric transaction in the electronic module 1. One end of the internal connection terminal 36 is electrically connected to the wiring 11 of the first board 10 or the electrodes 13a, 13b of the first electronic element 13. The other end of the internal connection terminal 36 is electrically connected with the wiring 21 of the second board 20 or the electrodes 23a, 23b of the second electronic element 23. Further, the internal connection terminal 36 is electrically connected to the external connection terminal 32 or the external connection terminal 34.

The internal connection terminal 36 electrically connects the first electronic element 13 and the external connection terminals 34a, 34b. To be more specific, as illustrated in FIG. 4A, FIG. 4B, the internal connection terminal 36c whose one end is disposed in the first electronic element 13 electrically connects the electrode 13a of the first electronic element 13 and the external connection terminal 34b to each other. Further, the internal connection terminal 36d electrically connects the electrode 13b of the first electronic element 13 and the external connection terminal 34a to each other.

The internal connection terminal 36 electrically connects the second electronic element 23 and the external connection terminals 32b, 34a, 34b to each other. To be more specific, as illustrated in FIG. 5A, FIG. 5B, the internal connection terminal 36b whose one end is disposed on the second electronic element 23 electrically connects the electrode 23a of the second electronic element 23 and the external connection terminals 32b, 34b to each other. Further, the internal connection terminal 36d electrically connects the electrode 23b of the second electrode element 23 and the external connection terminal 31a to each other.

The internal connection terminal 36 may be connected to the wiring 11 of the first board 10 and/or the wiring 21 of the second board 20. Further, the internal connection terminal 36 may be connected to the external connection terminals 32, 34. The internal connection terminal 36a of the electronic module 1 may be electrically connected to the wiring 11 of the first board 10, the wiring 21 of the second board 20, and the external connection terminal 32a.

With respect to the internal connection terminal 36, it is preferred that a cross-sectional area and a material of the internal connection terminal 36 are selected and the number of internal connection terminals 36 to be used is selected by taking into account an amount of current that flows through the internal connection terminal 36. For example, in the electronic module 1, the internal connection terminal 36b that electrically connects the electrode 23a of the second electronic element 23 and the external connection terminal 32b to each other has to treat a large current and hence, the internal connection terminal 36 includes three bold inner connection terminals 36b.

The external connection terminals 32a, 32b (in the description made hereinafter, “external connection terminals 32a, 32b” being collectively referred to as “external connection terminals 32” in some cases) are terminals that connect the wiring 11 of the first board 10, the electrodes 13a, 13b of the first electronic element 13, the wiring 21 of the second board 20 or the electrodes 23a, 23b of the second electrode 23, and the outside of the electronic module 1 to each other via the internal connection terminals 36.

The external connection terminal 32 is a power terminal that can treat a large current. As illustrated in FIG. 3, a portion of the external connection terminal 32 is disposed in a region between the first board 10 and the second board 20 in a state where the portion extends parallel to the first board 10 and the second board 20. Further, the external connection terminal 32 is configured such that at least one end of the external connection terminal 32 is exposed to the outside of the mold resin 40 and is connectable to an external terminal not illustrated in the drawing.

The external connection terminals 34a, 34b (in the description made hereinafter, “external connection terminals 34a, 34b” being collectively referred to as “external connection terminals 34”, or all of “external connection terminals 32a, 32b” and “external connection terminals 34a, 34b being collectively referred to as “external connection terminals 32, 34” in some cases) are terminals that connect the wiring 11 of the first board 10, the electrodes 13a, 13b of the first electronic element 13, the wiring 21 of the second board 20 and/or the electrodes 23a, 23b of the second electronic element 23 to the outside of the electronic module 1 via the internal connection terminals 36.

The external connection terminal 34 is a terminal that treats a smaller amount of current compared to the external connection terminal 32. As illustrated in FIG. 3, a portion of the external connection terminal 34 is disposed in a region between the first board 10 and the second board 20 in a state where the portion extends parallel to the first board 10 and the second board 20. Further, the external connection terminal 34 is configured such that at least one end of the external connection terminal 34 is exposed to the outside of the mold resin 40 and is connectable to an external terminal not illustrated in the drawing. Further, as illustrated in FIG. 5A, the external connection terminal 32 and the external connection terminal 34 may be mutually connected to each other as indicated as the external connection terminal 32b and the external connection terminal 34b.

Holes are formed in the external connection terminals 32, 34. The internal connection terminals 36 are made to pass through the corresponding holes. The external connection terminal 32, 34 is fixed at a predetermined position between one end to the other end of the internal connection terminal 36. With such a configuration, a distance between the first board 10 and the external connection terminal 32, 34 and a distance between the second board 20 and the external connection terminal 32, 34 can be controlled.

A length of the internal connection terminal 36, and a position at which the external connection terminals 32, 34 are connected to the internal connection terminals 36 are set such that a distance between either one of the first board 10 and the first electronic element 13 disposed at a position closer to the external connection terminal 32, 34 and the external connection terminal 32, 34 becomes longer than a predetermined insulation distance. Further, the length of the internal connection terminal 36, and the position of the internal connection terminal 36 at which the external connection terminals 32, 34 are connected to the internal connection terminal 36 are set such that a distance between either one of the second board 20 and the second electronic element 23 element disposed at a position closer to the external connection terminal 32, 34 and the external connection terminal 32, 34 becomes longer than a predetermined insulation distance.

To be more specific, a length of the internal connection terminal 36, and a position at which the external connection terminals 32, 34 are connected to the internal connection terminal 36 are set such that a distance between either one of the first board 10 and the first electronic element 13 element disposed at a position closer to the external connection terminal 32, 34 and the external connection terminal 32, 34 becomes longer than a predetermined insulation distance. Further, the length of the internal connection terminal 36, and the position at which the external connection terminals 32, 34 are connected to the internal connection terminal 36 are set such that a distance between either one of the second board 20 and the second electronic element 23 disposed at a position closer to the external connection terminal 32, 34 and external connection terminal 32, 34 becomes longer than a predetermined insulation distance.

The distance between the first board 10 and the external connection terminals 32, 34, and the distance between the first electronic element 13 and the external connection terminals 32, 34 can be adjusted by adjusting the length of the internal connection terminal 36 disposed between either the first board 10 or the first electronic element 13 and the external connection terminals 32, 34, and the position of the internal connection terminal 36 at which the external connection terminals 32, 34 are connected to the internal connection terminal 36.

The distance between the second board 20 and the external connection terminals 32, 34, and the distance between the second electronic element 23 and the external connection terminals 32, 34 can be adjusted by adjusting the length of the internal connection terminal 36 disposed between either the second board 20 or the second electronic element 23 and the external connection terminals 32, 34, and the position of the internal connection terminal 36 at which the external connection terminals 32, 34 are connected to the internal connection terminal 36.

In the electronic module 1 according to the embodiment, the first electronic element 13 is disposed at the position closer to the external connection terminals 32, 34 than the first board 10. The distance between the first electronic element 13 and the external connection terminals 32, 34 is indicated by L1. Further, the second electronic element 23 is disposed at the position closer to the external connection terminal 32, 34 than the second board 20. The distance between the second electronic element 23 and the external connection terminals 32, 34 is indicated by L2 (see FIG. 3).

The distance L1 between the first electronic element 13 and the external connection terminals 32, 34 is set longer than the insulation distance. Further, the distance L2 between the second electronic element 23 and the external connection terminals 32, 34 is set longer than the insulation distance. In such a configuration, the insulation distance is a distance that prevents the occurrence of short-circuiting (short) between the external connection terminals 32, 34 and the first board 10 or the second board 20.

By setting the distance L1 between the first electronic element 13 and the external connection terminals 32, 34, and the distance L2 between the second electronic element 23 and the external connection terminals 32, 34 longer than the insulation distance, the occurrence of the short-circuiting between the external connection terminals 32, 34 and the first electronic element 13 can be prevented and, at the same time, the occurrence of short-circuiting between the external connection terminals 32, 34 and the second electronic element 23 can be prevented.

In a case where the first board 10 is disposed at the position closer to the external connection terminals 32, 34 than the first electronic element 13, by exchanging the first electronic element 13 described above with the first board 10, it is possible to acquire the electronic module 1 that can prevent the occurrence of short-circuiting between the external connection terminals 32, 34 and the first board 10.

In a case where the second board 20 is disposed at the position closer to the external connection terminals 32, 34 than the second electronic element 23, by exchanging the second electronic element 23 described above with the second board 20, it is possible to acquire the electronic module 1 that can prevent the occurrence of short-circuiting between the external connection terminals 32, 34 and the second board 20.

The mold resin 40 seals a surface of the first board 10 on which the first electronic element 13 is disposed and the first electronic element 13 (see FIG. 2). Further, the mold resin 40 seals a surface of the second board 20 on a side where the second electronic element 23 is disposed and the second electronic element 23.

A heat radiation surface of the first board 10, that is, the surface of the first board 10 on which the first heat radiation member 12 is disposed, and a heat radiation surface of the second board 20, that is, the surface of the second board 20 on which the second heat radiation member 22 is disposed, are exposed from the mold resin 40.

The mold resin 40 has a first hollowed portion 41 and a second hollowed portion 42.

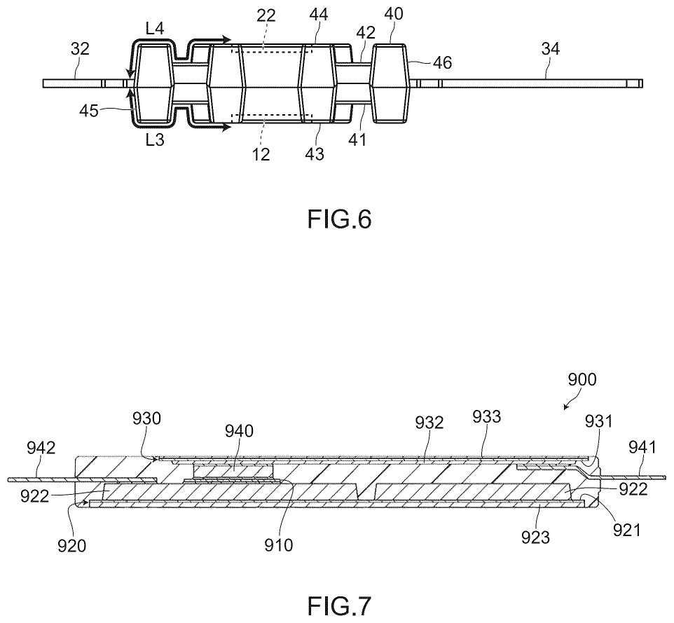

In the electronic module 1, the first hollowed portion 41 is formed on a surface 43 of the mold resin 40 where the first heat radiation member 12 is exposed (see FIG. 6). The first hollowed portion 41 is disposed between a boundary between a portion where the first heat radiation member 12 is exposed and a portion where the first heat radiation member 12 is covered by the mold resin 40, and an outer edge of the mold resin 40 that forms a profile of the mold resin 40, that is, an outer edge of the mold resin 40 that forms the profile in a direction where the external connection terminal 32 or the external connection terminal 34 extends.

In the electronic module 1, the second hollowed portion 42 is formed on a surface 44 of the mold resin 40 where the second heat radiation member 22 is exposed (see FIG. 2 and FIG. 6). The second hollowed portion 42 is disposed between a boundary between a portion where the second heat radiation member 22 is exposed and a portion where the second heat radiation member 22 is covered by the mold resin 40, and an outer edge of the mold resin 40 that forms the profile of the mold resin 40, that is, the outer edge of the mold resin 40 that forms the profile in a direction where the external connection terminal 32 or the external connection terminal 34 extends.

As illustrated in FIG. 2 and FIG. 6, in the electronic module 1, the first hollowed portion 41 is formed by hollowing (carving) the surface 43 where the first heat radiation member 12 is exposed from the mold resin 40. In the electronic module 1, the second hollowed portion 42 is formed by hollowing (carving) a surface 44 where the second heat radiation member 22 is exposed from the mold resin 40.

As illustrated in FIG. 2, the first hollowed portion 41 and/or the second hollowed portion 42 may be formed by hollowing the mold resin 50 over an entire circumference. Accordingly, the first hollowed portion 41 and the second hollowed portion 42 are joined to each other so that the mold resin 40 is formed in a neck shape.

The first hollowed portion 41 is formed such that a distance L3 taken along an outer surface of the mold resin 50 between the external connection terminal 32, 34 and the first heat radiation member 12 (hereinafter, “a distance L3 taken along an outer surface of the mold resin 50 between the external connection terminal 32, 34 and the first heat radiation member 12” being referred to as “a creepage distance L3”) is set longer than a predetermined insulation distance.

The second hollowed portion 42 is formed such that a distance L4 taken along an outer surface of the mold resin 50 between the external connection terminal 32, 34 and the first heat radiation member 12 (hereinafter, “a distance L4 taken along an outer surface of the mold resin 50 between the external connection terminal 32, 34 and the second heat radiation member 22” being referred to as “a creepage distance L4”) is set longer than a predetermined insulation distance.

With such a configuration, it is possible to prevent the occurrence of short-circuiting along a creepage (along an outer surface) of the mold resin 40 between the first heat radiation member 12 and the external connection terminal 32, 34. Further, it is possible to prevent short-circuiting along a creepage of the mold resin 40 between the second heat radiation member 22 and the external connection terminal 32, 34.

Further, the external connection terminals 32, 34 are disposed at a position of a middle point in a thickness direction between the first heat radiation member 12 disposed on the first board 10 and the second heat radiation member 22 disposed on the second board 20. That is, as illustrated in FIG. 6, the external connection terminals 32, 34 are disposed at a position where the creepage distance L3 between the external connection terminal 32, 34 and the first heat radiation member 12 and the creepage distance L4 between the external connection terminal 32, 34 and the second heat radiation member 22 are equal.

With such a configuration, in a case where a condition is satisfied that the creepage distance between the external connection terminal 32, 34 and the first heat radiation member 12 and the creepage distance L4 between the external connection terminal 32, 34 and the second heat radiation member 22 are longer than an insulation distance, it is possible to reduce a thickness of the electronic module 1 while preventing short-circuiting.

In such a configuration, in a case where the thickness of the external connection terminal 32, 34 is not uniform, “disposed at a position of a middle point in a thickness direction between the first heat radiation member 12 and the second heat radiation member 22” means that the external connection terminals 32, 34 that affect the decision of the insulation distance, that is, the external connection terminals 32, 34 having the largest thickness are disposed at the position of the middle portion in the thickness direction between the first heat radiation member 12 and the second heat radiation member 22.

Also with respect to the external connection terminals 32, 34, it is preferred to select a cross-sectional value (width, thickness) of the external connection terminal 32, 34 by taking into account an amount of current that flows through the external connection terminal 32, 34.

Hereinafter, advantageous effects that the electronic module 1 according to the embodiment acquires are described.

The electronic module 1 according to the embodiment includes the first board 10, the second board 20, the external connection terminals 32, 34, and the internal connection terminals 36 that are made to pass through the external connection terminal 32, 34. The internal connection terminals 36 are made to pass through the external connection terminal 32, 34, and fix the external connection terminal 32, 34 at a predetermined position between the first board 10 and the second board 20. In the electronic module 1 according to the embodiment, the distance between the first board 10 and the second board 20 is restricted by a length of the internal connection terminal 36. Accordingly, by controlling the length of the internal connection terminal 36, it is possible to control the distance between the first board 10 and the second board 20 properly without bending the external connection terminals 32, 34 or without using a thick board. Further, the external connection terminals 32, 34 are fixed at the predetermined position between the first board 10 and the second board 20 by the internal connection terminal 36 and hence, the distance between the first board 10 and the external connection terminals 32, 34 and the distance between the second board 20 and the external connection terminals 32, 34 can be also properly controlled. According to the electronic module 1 of the embodiment, it is possible to provide the electronic module 1 where the heat radiation surface is formed on both surfaces of the electronic module 1, and the external connection terminals 32, 34 are disposed between the first board 10 and the second board 20, wherein the distance between the first board 10 and the external connection terminal 32, 34 and the distance between the second board 20 and the external connection terminal 32, 34 can be properly controlled.

In the electronic module 1 according to the embodiment, the internal connection terminals 36 electrically connect the first electronic element 13 and the external connection terminal 32, 34 to each other. According to electronic module 1 of the embodiment, it is possible to supply a current to the first electronic element 13 from the external connection terminals 32, 34 via the internal connection terminals 36.

In the electronic module 1 according to the embodiment, the internal connection terminals 36 electrically connect the second electronic element 23 and the external connection terminal 32, 34 to each other. According to the electronic module 1 of the embodiment, it is possible to supply a current to the second electronic element 23 from the external connection terminals 32, 34 via the internal connection terminals 36.

In the electronic module 1 according to the embodiment, the length of the internal connection terminal 36, and the position of the internal connection terminal 36 at which the external connection terminals 32, 34 are connected to the internal connection terminals 36 are set such that a distance between the first board 10 and the first electronic element 13 disposed at the position closer to the external connection terminals 32, 34 and the external connection terminal 32, 34 becomes longer than the predetermined insulation distance. Further, the distance between either one of the second board 20 and the second electronic element 23 disposed at the position closer to the external connection terminals 32, 34 and the external connection terminal 32, 34 becomes longer than the predetermined insulation distance. Accordingly, it is possible to prevent the occurrence of short-circuiting (short) between the external connection terminal 32, 34 and the first board 10 and between the external connection terminal 32, 34 and the second board 20 and hence, it is possible to provide the highly reliable electronic module 1.

The electronic module 1 according to the embodiment further includes the mold resin 40. The first electronic element 13, the surface of the first board 10 on which the first electronic element 13 is disposed, the second electronic element 23, and the surface of the second board 20 on which the second electronic element 23 is disposed are sealed by the mold resin 40, and the heat radiation surface of the first board 10 and the heat radiation surface of the second board 20 are exposed from the mold resin 40. According to the electronic module 1, an insulation voltage can be increased without impairing a heat radiation characteristic and hence, it is possible to enhance the reliability of the electronic module 1.

As illustrated in FIG. 6, the electronic module 1 according to the embodiment further includes: the first hollowed portion 41 that is disposed on the surface 43 on which the first heat radiation member 12 is exposed from the mold resin 40; and the second hollowed portion 42 that is disposed on the surface 44 on which the second heat radiation member 22 is exposed from the mold resin 40. The first hollowed portion 41 is configured such that the creepage distance L3 taken along the outer surface of the mold resin 40 between the external connection terminal 32, 34 and the first heat radiation member 12 is set longer than the predetermined insulation distance. The second hollowed portion 42 is configured such that the creepage distance L4 taken along the outer surface of the mold resin 40 between the external connection terminal 32, 34 and the second heat radiation member 22 is set longer than the predetermined insulation distance. With such a configuration, the lengths of the creepage distances L3, L4 can be increased compared to a case where these hollowed portions 41, 42 are not provided. As a result, it is possible to prevent the occurrence of short-circuiting along the creepage surface of the mold resin 40 between the first heat radiation member 12 and the external connection terminals 32, 34 as well as between the second heat radiation member 22 and the external connection terminals 32, 34.

Although the present invention has been described based on the above-mentioned embodiments heretofore, the present invention is not limited to the above-mentioned embodiment. The present invention can be carried out in various modes without departing from the gist of the present invention. For example, the following modifications are also conceivable.

(1) The shapes, the numbers, the sizes, the positions and the like of the constitutional elements according to the present invention are not limited to the values illustrated in the above-mentioned description and the respective drawings, and the values can be suitably changed so long as the technical features of the present invention are not impaired.

To exemplify one example, in the above-mentioned embodiment, although the number of the first electronic elements 13 and the number of the second electronic elements 23 are respectively one, the present invention is not limited to such a case. The number of the first electronic elements 13 and the number of the second electronic elements 23 may be plural. Further, the electronic elements may be disposed on either one of the first board 10 or the second board 20.

(2) The electronic module according to the present invention may further include electronic elements, structures and the like besides the first electronic element 13 on the first board 10. Further, the electronic module according to the present invention may further include electronic elements, structures and the like besides the second electronic element 23 on the second board 20.

(3) As the first electronic element 13 in the electronic module according to the present invention, electronic elements other than a MOSFET (for example, various types of diodes, transistors other than a vertical MOSFET, a thyristor) can be also used. The same goes for the second electronic element 23.

1. An electronic module comprising:
a first board;
a first electronic element disposed on the first board;
a second board;
a second electronic element disposed on the second board;
an external connection terminal, and
an internal connection terminal made to pass through the external connection terminal, the external connection terminal being fixed to the internal connection terminal at a predetermined position between the first board and the second board, wherein
the internal connection terminal is disposed between the first board and the second board or the second electronic element, or, between the first electronic element and the second board or the second electronic element.

2. The electronic module according to claim 1, wherein the internal connection terminal is configured to electrically connect the first electronic element and the external connection terminal to each other.

3. The electronic module according to claim 1, wherein the internal connection terminal is configured to electrically connect the second electronic element and the external connection terminal to each other.

4. The electronic module according to claim 1, wherein a length of the internal connection terminal and a position of the internal connection terminal at which the external connection terminal is connected to the internal connection terminal are set such that, a distance between either one of the first board and the first electronic element disposed at a position closer to the external connection terminal and the external connection terminal becomes longer than a predetermined insulation distance, and a distance between either one of the second board and the second electronic element disposed at a position closer to the external connection terminal and the external connection terminal becomes longer than a predetermined insulation distance.

5. The electronic module according to claim 1, further comprising a mold resin, wherein the first electronic element, a surface of the first board on which the first electronic element is disposed, the second electronic element, and a surface of the second board on which the second electronic element is disposed are sealed by the mold resin, and a heat radiation surface of the first board and a heat radiation surface of the second board are exposed from the mold resin.

6. The electronic module according to claim 5, further comprising: a first heat radiation member disposed on the first board: a second heat radiation member disposed on the second board; a first hollowed portion that is disposed on a surface of the mold resin on which the first heat radiation member is exposed; and a second hollowed portion that is disposed on a surface of the mold resin on which the second heat radiation member is exposed, wherein
the first hollowed portion is configured such that a creepage distance taken along an outer surface of the mold resin between the external connection terminal and the first heat radiation member is set longer than a predetermined insulation distance, and
the second hollowed portion is configured such that a creepage distance taken along the outer surface of the mold resin 40 between the external connection terminal and the second heat radiation member is set longer than a predetermined insulation distance.
